(19) United States
(12) Patent Application Publication
(10) Pub. No.: US 2009/0075421 A1
(43) Pub. Date: Mar. 19, 2009

(54) Wet etching of zinc tin oxide thin films

(75) Inventors: Zhizhang Chen, Corvallis, OR (US); Eric Wiedemann, Corvallis, OR (US); Qin Liu, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: Hewlett-Packard Development Company, L.P., Houston, TX (US)

(21) Appl. No.: 11/901,852

(22) Filed: Sep. 19, 2007

(51) Int. Cl. H01L 21/34; C23F 1/00

(52) U.S. Cl. 438/104; 156/345.11; 257/E21.486

(57) ABSTRACT

A method of wet etching semiconductor zinc tin oxide includes submerging a semiconductor zinc tin oxide film in a bath solution. The film is partially covered with a pattern of protective material, and the bath solution etches semiconductor zinc tin oxide film not covered by the protective material. A system for wet etching semiconductor zinc tin oxide includes a bath containing a bath solution. The bath solution is effective to wet etch the semiconductor zinc tin oxide.

### BACKGROUND

Various compositions of zinc tin oxide (ZTO) are suitable for use as a transparent conductors or semiconductors. The composition of ZTO that forms a semiconductor material is particularly resistant to chemical etching. This has previously prevented patterning of semiconductor ZTO using known wet bath etching solutions and processes.

### BRIEF DESCRIPTION OF THE DRAWINGS

The accompanying drawings illustrate various embodiments of the principles described herein and are a part of the specification. The illustrated embodiments are merely examples and do not limit the scope of the claims.

FIG. 1 is a top view of an illustrative ZTO test piece, according to principles described herein.

FIG. 2 is a detailed view of an illustrative pattern within a ZTO test piece, according to principles described herein.

FIG. 3 is a cross-sectional view of an illustrative ZTO test piece, according to principles described herein.

FIG. 4 is a cross-sectional view of an illustrative ZTO test piece, according to principles described herein.

FIG. 5 is a cross-sectional view of an illustrative ZTO test piece, according to principles described herein.

FIG. 6 is a cross-sectional view of an illustrative ZTO test piece, according to principles described herein.

FIG. 7 is a diagram representing the results from an Auger scan of a portion of an illustrative ZTO test piece, according to principles described herein.

FIG. 8 is a diagram showing the etch rates of an illustrative semiconductor ZTO in a wet etch bath as a function of time, according to principles described herein.

FIG. 9 is a diagram showing the etch rates of an illustrative semiconductor ZTO in a wet etch bath as a function of time, according to principles described herein.

FIG. 10 is a diagram showing the post-etch uniformity measurements of illustrative ZTO test pieces, according to principles described herein.

FIG. 11 is a diagram showing the nominal etch rate of illustrative ZTO test pieces in a wet etch bath, according to principles described herein.

FIG. 12 is an illustrative flowchart showing one exemplary embodiment of the process of wet etching a ZTO thin film, according to principles described herein.

FIG. 13 is an schematic diagram of an illustrative system for wet etching a ZTO thin film, according to principles described herein.

Throughout the drawings, identical reference numbers designate similar, but not necessarily identical, elements.

### DETAILED DESCRIPTION

The present invention relates to the fabrication of electro-active layers of zinc tin oxide (ZTO), and particularly to fabricating thin film transistors. ZTO has an amorphous structure with good electrical mobility, physical strength, scratch resistance, high chemical stability and resistance to chemical etching, low cost, and a smooth surface. ZTO is a low-cost replacement for indium tin oxide (ITO, or tin-doped indium oxide). ZTO can be used to produce either a conductive or semiconductive thin film.

ZTO can be used for a variety of applications. Examples include transparent conductive or semi-conductive elements in liquid crystal displays, flat-panel displays, plasma displays, patch panels, electronic paper, organic light emitting diodes, solar cells, antistatic and electromagnetic interference (EMI) coatings and gas sensors, and can be used for various optical coatings and strain gauge technology.

Conductive and semi-conductive ZTO films contain different zinc/tin ratios and have substantially dissimilar chemical characteristics. Zinc oxide, or compounds that contain primarily zinc oxide, are relatively easily etched. Wet etching processes for zinc compounds that contain primarily zinc oxide are well known. When a majority percentage of zinc oxide is combined with a minority percentage of tin oxide, a transparent conductive film is created that is suitable for electrodes or traces.

Tin oxide, or compounds that contain primarily tin oxide, are very difficult to etch and require expensive and time consuming patterning methods (such as dry etching in a high vacuum system followed by plasma ashing of the photoresist). Tin oxide, when combined with zinc oxide in ratios of about 1:1 forms a semiconductor that is suitable for making transparent thin film transistors. However, no process has existed traditionally for successfully wet etching such thin films. Particularly, the known methods used for wet etching zinc oxide do not work on ZTO semiconductor films.

ZTO films may be deposited by a range of sputter deposition techniques, electron beam evaporation, physical vapor deposition, chemical spray pyrolysis, or a range of other techniques. Significantly, some of these techniques allow low temperature applications of the ZTO films to substrates. This allows the deposition of ZTO films as transparent electrodes and semiconductors onto plastic and/or flexible substrates.

As indicated, because of semiconducting ZTO's resistance to chemical attack, wet etch patterning for ZTO films is unknown conventionally. Therefore, electrode patterning of ZTO semiconductor structures has typically been produced using shadow mask, lift-off, or dry etch processes. However both lift-off and shadow mask processes are difficult to scale up to practical production volumes.

The shadow mask process is a research laboratory process. The shadow mask process typically deposits the zinc tin oxide ions in a specific pattern on the substrate by magnetron sputtering through a shadow mask. However, dimensions are not well controlled and a high amount of manual intervention is required for each shadow mask set up. Because the shadow mask process is time consuming and requires manual adjustment to each set up, it is not well adapted for mass production. In addition, there are limits to the resolution and size of the patterning produced on flexible substrates using shadow mask process.

Another technique for patterning thin films, especially hard to etch films, is the lift-off technique. In this technique, a masking layer is applied to a surface and is patterned in a reverse pattern, i.e., the masking layer is removed from areas where the thin film is to remain in the final structure. The thin film is applied over the masking layer and in openings through the masking layer. The masking layer is then stripped away, removing the thin film overlying the masking layer and leaving the desired thin film pattern on the underlying surface. However, there is an inherent lack of uniformity in removing the thin film using the lift-off technique. The thin film forms a continuous surface over the substrate, with portions of the thin film adhering to the masking layer and other portions adhering to the substrate. As the masking layer is stripped away, there is always some part of the thin film unintentionally left behind. There is also a portion of the thin film that is unintentionally removed. This lack of uniformity leads to an increased likelihood of circuit failure.

Because of the difficulties with the shadow mask and lift-off techniques, the primary method conventionally of patterning ZTO is dry etching. As indicated above, wet etching for ZTO films is unknown conventionally. Dry etching involves exposing a masked pattern to a bombardment of ions. The ions remove material from the exposed surfaces. Portions of a semiconductor or conductor thin film that are covered by a cured photoresist layer are protected from the ion bombardment and are left intact. Unprotected areas of the thin film are etched by the ion bombardment. The ions are typically created from nitrogen, chlorine, or boron trichloride. The dry etch process creates local heating which can become a problem when the substrate has a low melting point and/or low thermal conductivity.

The ion bombardment process must take place in an enclosed, high vacuum environment, which is an expensive and slow process. For each batch, the substrates must first be loaded into the vacuum container, the container must be closed and sealed, and a vacuum created in the container. Typically dry etching occurs at pressures below 1 Torr for sufficient ion mobility and the reduction of contaminants. After the desired amount of film is removed by dry etching, plasma ashing is used to remove the photoresist.

Plasma ashing is the process of removing the photoresist from an etched substrate. Similar to dry etching, plasma ashing must be performed in a high vacuum environment. Using a plasma source, monotonic reactive species are generated. The oxygen or fluorine plasma is the most common reactive species. The reactive species combines with the photoresist to form ash which is removed by a vacuum pump. During the ashing process, free radicals are formed which can damage the wafer or film. Newer, smaller circuitry is increasingly susceptible to these free radicals. Ash particulates are also generated, which have the potential to contaminate the circuitry.

There is a clear need for a practical, low cost technique for effectively etching semiconductor ZTO thin films. Ideally, the etching process would be compatible with low temperature plastic substrates and be easy to scale up to manufacturing volumes.

In the following description, for purposes of explanation, numerous specific details are set forth in order to provide a thorough understanding of the present systems and methods. It will be apparent, however, to one skilled in the art that the present apparatus, systems and methods may be practiced without these specific details. Reference in the specification to “an embodiment,” “an example” or similar language means that a particular feature, structure, or characteristic described in connection with the embodiment or example is included in at least that one embodiment, but not necessarily in other embodiments. The various instances of the phrase “in one embodiment” or similar phrases in various places in the specification are not necessarily all referring to the same embodiment.

Wet etching is used in micro-fabrication to chemically remove layers from the surface of a substrate during manufacturing. In a wet etch, the wafer can be submerged in a bath of acid or other reactive solution which chemically attacks areas that are unprotected by a photoresist layer or other non-reactive layer. Additionally the wet etch bath may be tailored to preferentially attack specific materials. Wet etching is a standard patterning process within the semiconductor industry. Wet etching is practical, inexpensive, easy to scale up to manufacturing volumes, and compatible with large-scale work pieces.

To discover how to wet etch ZTO, the applicant's have experimented with a wide number of agent ratios, temperatures and times The following chart summarizes a few of these experimental tests performed to determine if a viable wet etch process for semiconductor ZTO could be found.

CHART 1
Experimental Data

| Test # | HCl | HNO₃ | H₂O | T (° C.) | Time (min) | Response |
|---|---|---|---|---|---|---|
| 1 | 5 | 1 | 9 | 35 | 5 | No |
| 2 | 3 | 1 | 16 | 30 | 5 | No |
| 3 | 3 | 1 | 10 | 30 | 5 | No |
| 4 | 3 | 1 | 4 | 30 | 5 | No |
| 5 | 0 | 1 | 1 | 30 | 5 | No |
| 6 | 3 | 1 | 3 | 30 | 5 | Yes |
| 7 | 1 | 0 | 0 | 30 | 5 | Yes |
| 8 | 1 | 3 | 3 | 35 | 5 | No |
| 9 | 8 | 1 | 9 | 35 | 5 | No |
| 10 | 9 | 1 | 3 | 35 | 5 | Yes |

The first column, labeled “Test #,” is a sequential numeric index to the different experimental tests that were performed. The second column, labeled “HCl,” contains a numeric integer that represents the proportion of hydrochloric acid that was used in a particular bath solution. The third column, labeled “HNO₃,” contains a numeric integer that represents the proportion of nitric acid that was used in a particular bath solution. Both the hydrochloric acid and the nitric acid used in the bath solutions were semiconductor grade acids with a concentration of 70%. The fourth column, labeled “H₂O,” contains a numeric integer that represents the proportion of deionized water that was used in a particular solution. The fifth column, labeled “T (° C.),” represents the bath temperature in degrees Celsius. The sixth column, labeled “Time (min)” represents the time in minutes that the ZTO test piece was submerged in the bath solution. The seventh column, labeled “Response,” represents a subjective determination of the effectiveness of the bath solution in etching the semiconductor ZTO layer. The subjective determination was made by comparing the color of an unetched ZTO layer with the color of an etched ZTO layer, where both had the same initial thickness. A color change indicates a change in thickness of the etched layer.

Tests 1 through 5 showed no etching of the ZTO layer. Test 6, with a bath solution comprised of 3:1:3 ratio of hydrochloric:nitric:water mixture at 30° C. successfully etched the ZTO layer. Test 7, with a bath solution comprised of only of hydrochloric acid at 30° C. successfully etched the ZTO layer. Test 8, with a bath solution comprised of 1:3:3 ratio of hydrochloric:nitric:water at 35° C. was unsuccessful in etching the ZTO layer. Similarly, test 9, with a bath solution comprised of 8:1:9 ratio of hydrochloric:nitric:water at 35° C. was unsuccessfully in etching the ZTO layer. The 8:1:9 ratio of hydrochloric:nitric:water is an etchant for the thin film material indium tin oxide. Test 10, with a bath solution comprised of 9:1:3 ratio of hydrochloric:nitric:water at 35° C. successfully etched the ZTO layer.

The results of these tests seem to indicate that the ZTO etching byproducts have a narrow window of solubility within the hydrochloric:nitric:water bath. Throughout the remainder of this specification, the discussion and data refer to the bath solution used in test 10, namely a bath solution comprised of a 9:1:3 ratio of hydrochloric:nitric:water.

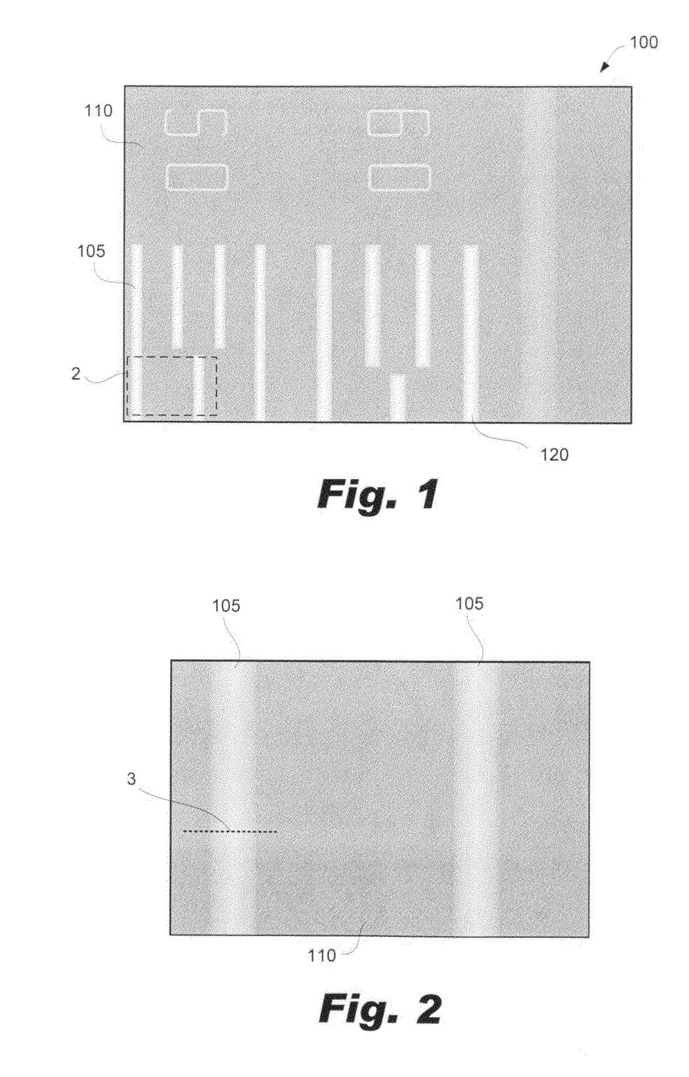

FIG. 1 shows a top view of a ZTO patterned test piece. The darker areas (110) in the diagram show regions where the semiconductor ZTO material has been etched away by submerging the test piece in a bath solution comprised of a 9:1:3 ratio of hydrochloric:nitric:water. The removal of the ZTO thin film exposes the darker underlying substrate. The lighter areas (105) are the remaining ZTO thin film after the photoresist which covered and protected it during the wet etch processing has been stripped away. The dotted rectangle (2) indicates an area shown in the detailed view in FIG. 2.

FIG. 2 shows a magnified view of the indicated portion of the ZTO test piece from FIG. 1. Two semiconducting ZTO traces (105) with an approximate width of 50 microns are shown traversing FIG. 2 from top to bottom. On either side of the traces, the semiconducting ZTO layer has been etched away, exposing the underlying substrate. In this case, the semiconducting ZTO layer has been deposited on a silicon dioxide substrate. The dotted line (3) shows the location where test piece was cut across a trace to measure the thickness of the semiconducting ZTO layer using a tunneling electron microscope.

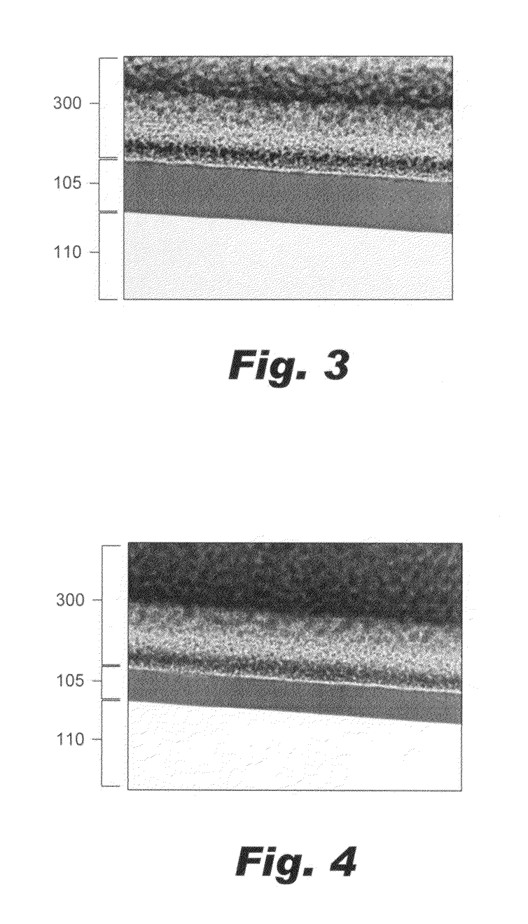

FIGS. 3-7 show tunneling electron microscope images of the cross-sections of the test piece taken along the line (3) shown in FIG. 2. The light colored layer at the bottom of FIG. 3 is the silicon dioxide substrate (110). On top of the silicon dioxide substrate (110) is the semiconducting ZTO trace (105). Above the semiconducting ZTO layer (105), a layer of platinum (300) that has been deposited on top of the test piece as a prerequisite requirement for making a tunneling electron microscope measurement. Neither the silicon dioxide substrate (110) nor the semiconducting ZTO trace (105) is highly electrically conductive. The platinum layer (300) is added as a conductive layer to transport the charged particles generated during the tunneling electron microscope measurement to an external electrical ground. The cross-sectional region imaged by FIG. 3 is near the middle of the semiconducting ZTO trace (105) and has the thickest ZTO layer.

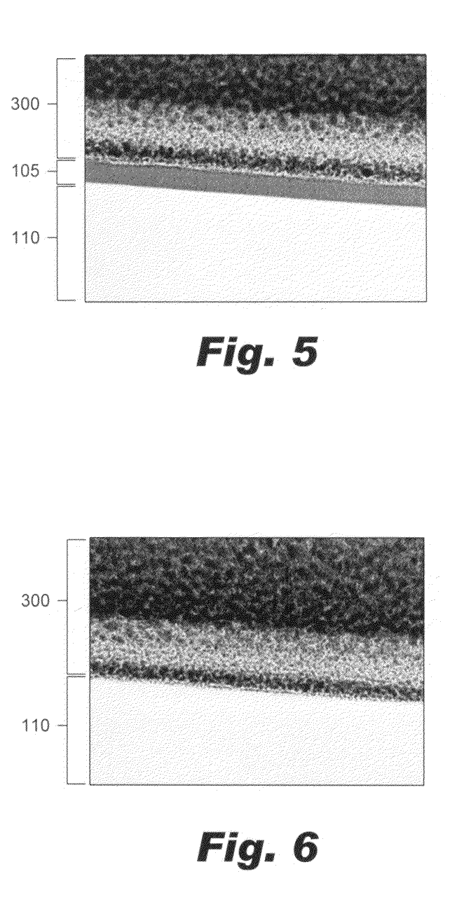

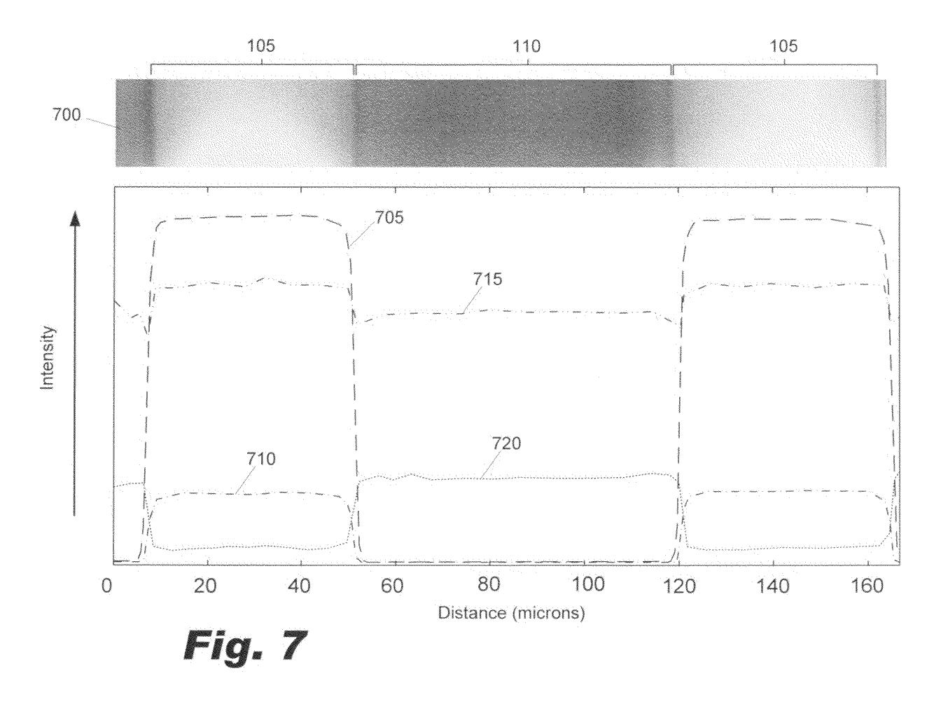

FIGS. 4 and 5 show decreasing thickness of the ZTO trace (105) as additional measurements are made progressively closer to the outer edge of the trace. FIG. 6 is taken at the edge of the trace where no ZTO layer is apparent. This series of images shows that thickness of the ZTO layer gradually decreases from the center to the edge of the trace (105).

FIG. 7 shows the results of Auger scan which was performed on a ZTO test piece (700). The top portion of FIG. 7 is an image, shown from a bird's eye view, of a portion of the test piece (700). The image was generated by a scanning electron microscope and represents the region tested in the Auger scan. In the test piece (700), the ZTO traces (105) are again about 50μ wide. The traces (105) are separated by an etched region (110) of about 65 microns in width.

The lower portion of FIG. 7 shows an Auger scan of the area shown in the upper portion. Auger electron spectroscopy probes the composition chemistry of a surface by measuring the energy of electrons emitted by the surface when it is a radiated with electrons of energy in the range of 2 to 50 keV. The radiating electrons typically only penetrate a few nanometers into the surface, and thus the Auger scan measures only surface chemistry. The Auger effect occurs because the incident electrons can remove a core state electron from an atom in the surface being scanned. This core state can be filled by an outer shell electron from the same atom. As the outer shell electron moves to a lower energy state, the difference between the orbital energies is released to a second outer shell electron which is ejected from the atom. This ejected electron and its associated energy is sensed by the Auger probe. Because the difference between the orbital energies is unique to each element, the Auger scan can identify the surface composition of a test piece.

The horizontal axis of the graph represents the cross-sectional distance across the test area measured in microns. The vertical axis represents the magnitude or intensity of the received signal as the Auger probe moves over the test piece.

The line (705) represents the measured amount of tin on the surface of the test piece (700). As can be seen from the graph, the tin measured by the Auger scan has a large and relatively constant magnitude as the probe passed over the ZTO traces (105). In the etched region (110) between the ZTO traces (105), the measurement of tin in the surface of the test piece is negligible.

Similarly, the line (710) represents the measured amount of zinc on the surface of the test piece (700). The zinc measurement shows a relatively constant magnitude as the probe passes over the ZTO traces (105) and a negligible magnitude in the etched region (110) in between the traces (105).

The relative magnitudes of the tin (705) and the zinc (710) measurements do not directly correspond to the proportion of the two materials physically present in the ZTO trace. The measured magnitude of an Auger scan is influenced by a variety of factors including the atomic weight of the element, surface chemistry, the energies of the radiating electrons, and other parameters.

Line (715) represents the measured amount of oxygen on the surface of the test piece (700). Oxygen is a component in both the ZTO layer and the underlying silicon oxide substrate. The Auger scan shows that oxygen is measured across the entire tested region, with a slightly higher response from the oxygen contained within the traces (105).

Line (720) represents the Auger emission of electrons by silicon on the surface of the test piece (700). The largest magnitude is in between the traces (105) where the silicon oxide substrate has been exposed by the wet etch process.

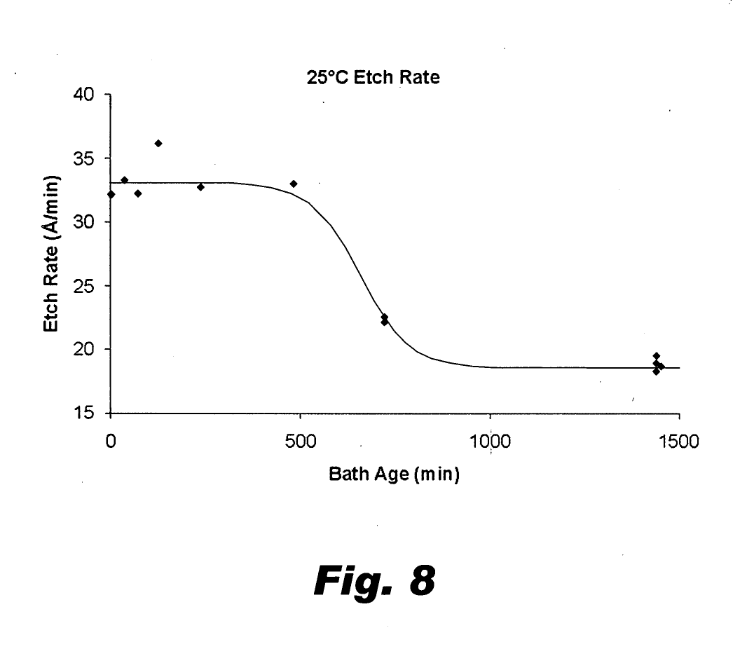

FIG. 8 shows etch rate as a function of bath age for a solution at 25° C. As previously mentioned, the bath solution is initially comprised of a 9:1:3 ratio of hydrochloric:nitric:water. The horizontal axis represents the bath age in minutes. The bath age is measured from the initial combination and agitation of the bath solution. The vertical axis represents the etch rate of the ZTO layer in angstroms per minute. The data points on the graph represent change in the thickness of a ZTO layer in microns divided by the length of time the ZTO layer was submerged in the bath solution. In general, the etch rate appears to be fairly steady for the first eight hours of bath life. This is followed by a rapid drop to about 60% of the initial etch rate. All pre-and post-etch ZTO layer thicknesses were measured by ellipsometry.

The continuous line through the data points is a function implied by a regressive analysis that minimizes the difference between the data points and the function. The shape of the function suggests the consumption of one or more reactants in the bath solution by autocatalytic or collectively autocatalytic means. The function follows a “logistic curve” where a chemical reaction initially proceeds slowly because there is little catalyst present, then rate of reaction increases progressively as the reaction proceeds and the amount of catalyst increases. The reaction slows down again as the reactant concentration decreases, and stops when the reactant is substantially consumed.

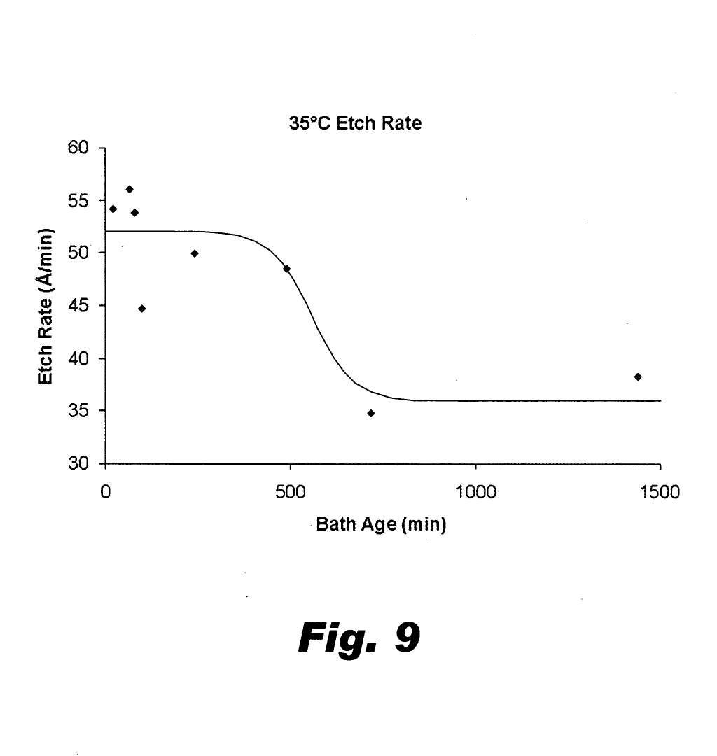

FIG. 9 shows the etch rate of a ZTO layer in angstroms per minute as a function of bath age for a solution temperature of 35° C. Similar to the diagram shown in FIG. 8, the etch rate follows a “logistic curve” decay pattern.

Over the first eight hours of bath age, the etch rate of the ZTO layer in a bath solution comprised of a 9:1:3 ratio of hydrochloric:nitric:water was 33.4 Å per minute at 25° C. and 54.5 Å per minute at 35° C. The “equilibrium” (long bath age) etch rates were about 18 Å per minute at 25° C. and 36 Å per minute and 35° C. This follows the “wet etch rule of thumb,” that the etch rate approximately doubles for a temperature increase of 10° C.

The logistic curve in FIGS. 8 and 9 can be represented by the equation:

$$R ( t ) = a * \frac{1 + {me}^{- \frac{t}{τ}}}{1 + {ne}^{- \frac{t}{τ}}}$$

where the constants are defined in chart 2.

CHART 2
Logistic Curve Coefficients

| | a (Å/min) | m (—) | n (—) | τ (min) |
|---|---|---|---|---|
| 25° C. | 18 | 4.46 × 10⁴ | 2.50 × 10⁴ | 65 |
| 35° C. | 36 | 3.61 × 10⁴ | 2.50 × 10⁴ | 55 |

Etching uniformity can be important in some applications and measures the differences in the amount of material etched by the bath at different location on a single wafer or between different wafers. The etching rate can vary based on a variety of factors including the physical motion of the bath solution. The bath solution may be agitated to improve etching uniformity and etching rate. The motion of the bath solution typically increases the etch rate by physically conveying the chemically etched byproducts that are suspended in the solution way from the test piece surface. Baffles can be used to control this convective motion, yielding a more uniform etch rate across a single wafer and between multiple wafers.

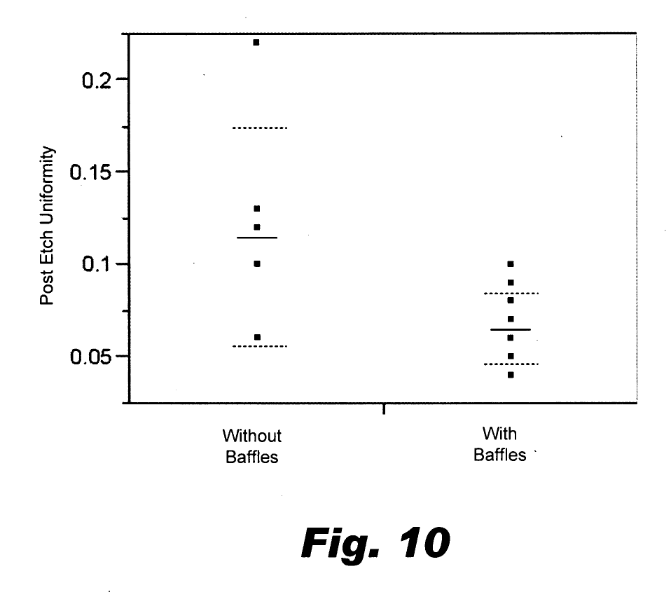

FIG. 10 shows the post-etch uniformity with and without baffles. In this case, the baffles were used to simulate a full boat of 25 wafers. The data points represent the deviation of the etch rate from a standard for locations measured over the surface of a single wafer. The chart below contains a statistical summary of the data contained in FIG. 10.

CHART 3
Post Etch Uniformity Statistics

| | Mean | Std. Deviation |
|---|---|---|
| Without Baffles | .115 | .059 |
| With Baffles | .065 | .019 |

Without the baffles, the mean uniformity was approximately 0.115 with a standard deviation of 0.059. With baffles, the post etch uniformity was approximately 0.065 with a standard deviation of 0.019. The median for each data set is represented in FIG. 10 as a solid line and the upper and lower standard deviation limits are represented by dotted lines.

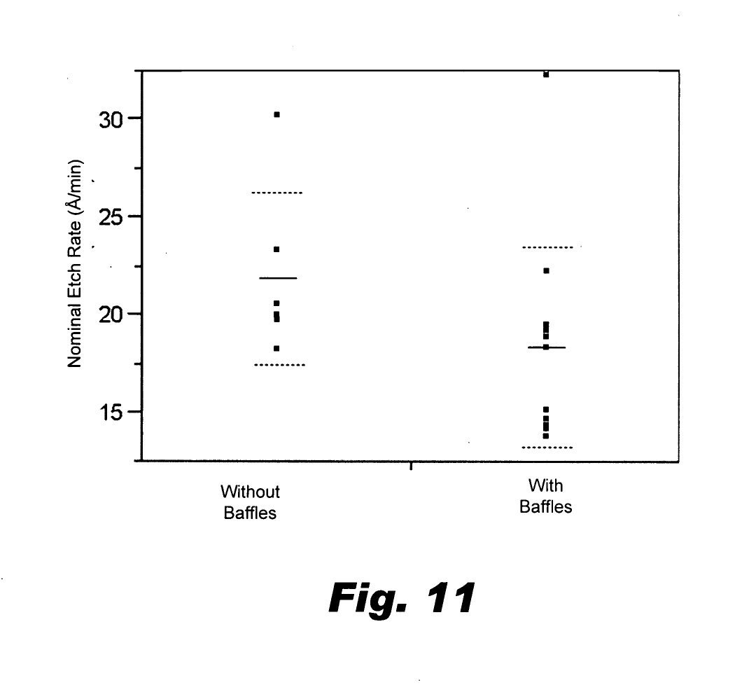

FIG. 11 shows the nominal etch rate in angstroms per minute compared between a baffles and non-baffled configuration. Baffles typically reduce effects of bath solution motion, but may also reduce the etch rate.

CHART 4
Nominal Etch Rate Statistics

| | Mean | Std. Deviation |
|---|---|---|
| Without Baffles | 21.9 | 4.38 |
| With Baffles | 18.4 | 5.11 |

As shown in FIG. 11, the non-baffled etch rate is higher, with about 21.9 Å per minute of ZTO material removed. The standard deviation for the sample is 4.39 Å per minute. The baffled etch rate as shown on the right-hand side of FIG. 11 has a mean etch rate of 18.4 Å per minute and a standard deviation of 5.11 Å per minute. The median for each data set is represented in FIG. 11 as a solid line, and the upper and lower standard deviation limits are represented by dotted lines.

As can be seen from FIGS. 10 and 11, the wafer etch rate uniformity (defined as standard deviation divided by the mean) improved by about 40%, while the etch rate decreased only by about 15%. The decrease in etch rate and improved uniformity corresponds to more uniform chemical transport of the chemical byproducts within the bath.

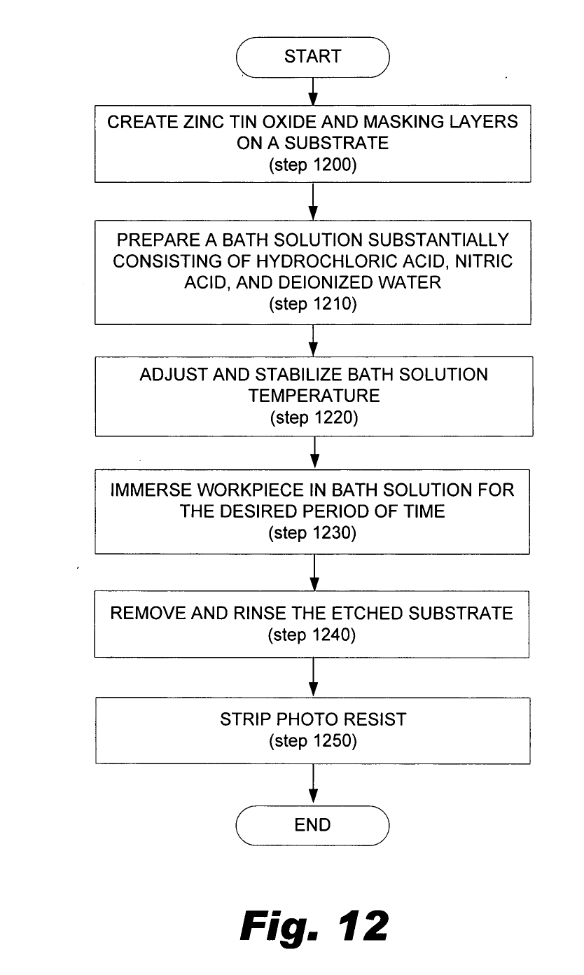

FIG. 12 shows one illustrative embodiment of a method of etching the ZTO semiconductor films using a hydrochloric and nitric acid bath. The first step (1200) is to deposit a semiconducting ZTO thin film and masking layers on a substrate. This step can be accomplished by a variety of means known in the art including deposition of ZTO on the substrate followed by the application of a photo resist layer which is patterned by lithography. Following the exposure of the photo resist layer, the exposed area of the resist would be removed, thereby exposing areas of the semiconductor ZTO film that are to be etched away.

The second step (1210) is to prepare a bath solution substantially consisting of a mixture of hydrochloric acid, nitric acid, and deionized water. This solution may be agitated to ensure a uniform mixture. The temperature of the bath may be adjusted, if necessary, and stabilized at the desired temperature (1220).

The fourth step (1230) is to immerse the substrate in the bath solution for a desired period of time. The immersion time is a function of a variety of factors and varies from situation to situation. By way of example and not limitation, the immersion time could be a function of the temperature of the bath, the thickness of the film being etched, age of the bath solution, the chemical composition of the semiconducting ZTO film, the geometry of the test piece, the motion of the bath solution, and other factors.

The fifth step (1240) is to remove the etched workpiece from the solution. Typically, the workpiece is rinsed to remove residual bath solution from the surface of the workpiece and then dried. The photoresist is then stripped from the surface using chemical or other methods. At this point, the ZTO layer has been patterned and the workpiece can proceed to the next process in the work flow.

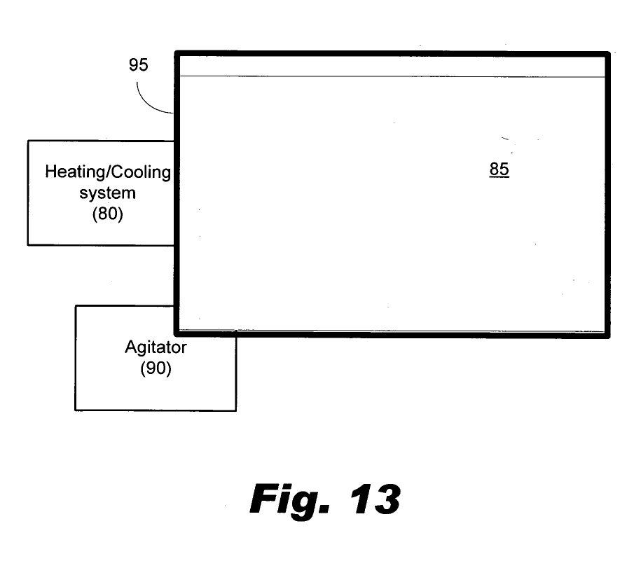

FIG. 13 shows an exemplary system for wet etching a semiconductor zinc tin oxide film. As shown in FIG. 13, a bath (95) is provided. The bath (95) can be sized as best suits a particular application. For example, the bath (95) can be made large enough to accommodate workpieces for ZTO wet etching on an industrial or manufacturing scale.

The bath (95) contains a bath solution (85) that is effective to wet etch ZTO thin films. For example, the bath solution (85) as described herein may be a solution comprised of a 9:1:3 ratio of hydrochloric acid, nitric acid and water. The water may be deionized.

The bath (95) also includes a heating/cooling system (80). The heating/cooling system (80) allows for control of the temperature of the bath solution. In some embodiments, the bath solution is maintained at a temperature between 20° C. and 50° C. by the heating system (90).

Additionally, the bath (95) also includes an agitator (90) for agitating the solution (85) within the bath. As described above, the bath solution may be agitated to improve etching uniformity and etching rate. The motion of the bath solution typically increases the etch rate by physically conveying the chemically etched byproducts that are suspended in the solution way from the test piece surface. Baffles can be used to control this convective motion, yielding a more uniform etch rate across a single wafer and between multiple wafers.

Consequently, the present specification provides a much needed technique for wet etching ZTO films into desired patterns. As noted above, ZTO film tend to resist wet etching and, prior to the discoveries described herein, could not be readily etched by a process that was both effective in terms of cost and time and scalable up to manufacture levels.

The preceding description has been presented only to illustrate and describe embodiments and examples of the principles described. This description is not intended to be exhaustive or to limit these principles to any precise form disclosed. Many modifications and variations are possible in light of the above teaching.

What is claimed is:

1. A method of wet etching semiconductor zinc tin oxide comprising submerging a semiconductor zinc tin oxide film in a bath solution, wherein said film is partially covered with a pattern of protective material and said bath solution etches semiconductor zinc tin oxide film not covered by said protective material.

2. The method of claim 1, wherein said protective material comprises photoresist.

3. The method of claim 1, wherein said bath solution initially comprises hydrochloric acid.

4. The method of claim 1, wherein said bath solution initially comprises nitric acid.

5. The method of claim 3, wherein said bath solution also comprises nitric acid.

6. The method of claim 5, wherein said bath solution also comprises water.

7. The method of claim 6, wherein said bath solution comprises:
semiconductor grade hydrochloric acid with a concentration of about 70%, said hydrochloric acid initially comprising 100 to 42 parts per hundred;
semiconductor grade nitric acid with a concentration of about 70%, said nitric acid initially comprising 14 parts per hundred to zero parts per hundred; and
water.

8. The method of claim 1, wherein said bath solution initially comprises about 69 parts per hundred hydrochloric acid, about 8 parts per hundred nitric acid, and about 23 parts per hundred deionized water.

9. The method of claim 8, wherein said bath solution is maintained at a temperature between 20° C. and 50° C.

10. The method of claim 1, wherein said bath solution is maintained at a temperature between 20° C. and 50° C.

11. The method of claim 1, further comprising depositing said semiconductor zinc tin oxide as a thin film on a substrate prior to said submerging.

12. The method of claim 11, further comprising depositing and patterning said protective material on said thin film of semiconductor zinc tin oxide.

13. The method of claim 12, wherein said patterning configures said semiconductor zinc tin oxide as a semiconductor channel layer in a thin film transistor.

14. The method of claim 12, wherein said semiconductor zinc tin oxide is deposited on said substrate by magnetron sputtering of a precursor target comprising zinc oxide and tin oxide.

15. The method of claim 14, wherein said semiconductor zinc tin oxide precursor contains at least 40% tin oxide.

16. A system for wet etching semiconductor zinc tin oxide comprising:
a bath containing a bath solution; and
said bath solution;
wherein said bath solution is effective to wet etch said semiconductor zinc tin oxide.

17. The system of claim 16, further comprising means for agitating said bath solution in said bath.

18. The system of claim 16, wherein said bath solution initially comprises about 70 parts per hundred hydrochloric acid, about 8 parts per hundred nitric acid, and about 23 parts per hundred deionized water.

19. The system of claim 16, wherein said bath solution comprises:
semiconductor grade hydrochloric acid with a concentration of about 70%, said hydrochloric acid initially comprising 100 to 42 parts per hundred;
semiconductor grade nitric acid with a concentration of about 70%, said nitric acid initially comprising 14 parts per hundred to zero parts per hundred; and
water.

20. The system of claim 16, wherein said bath solution is maintained at a temperature between 20° C. and 50° C.
